(19) United States
(12) Patent Application Publication
(10) Pub. No.: US 2007/0096121 A1
(43) Pub. Date: May 3, 2007

(54) Light emitting diode and method for manufacturing the same

(76) Inventors: Ying Chia Ni, Hsinchu (TW); Kuo Yen Nee, Hsinchu (TW); Ming Cheng Hung, Hsinchu (TW)

Correspondence Address: LIN & ASSOCIATES INTELLECTUAL PROPERTY, P.O. BOX 2339, SARATOGA, CA, 95070-0339, US

(21) Appl. No.: 11/262,233

(22) Filed: Oct. 28, 2005

(51) Int. Cl. H01L 31/12

(52) U.S. Cl. 257/82; 257/E33.026

(57) ABSTRACT

A light emitting diode and a method for manufacturing the same are provided. The light emitting diode includes: a transparent substrate made of AlₓGa₁₋ₓAs; a light emitting layer made of AlGaInP, stacked on the transparent substrate, and having a multiple layered epitaxially growing structure; a window layer made of GaP, stacked on the light emitting layer, and having a transparent structure with a great bandgap; an upper electrode layer overlying the window layer; and a lower electrode layer underlying the transparent substrate, wherein the x-value in AlₓGa₁₋ₓAs is set to corresponding to the emission wavelengths of the light emitting layer so that the transparent substrate can have a great bandgap which make it to be transparent to the light emitted by the light emitting layer; and a window layer is used to increase the current diffusion from the upper electrode layer to the light emitting layer.

### BACKGROUND OF THE INVENTION

1. Field of the Invention

The present invention relates generally to a light emitting diode and a method for manufacturing such a light emitting diode, and in particular to a light emitting diode made of III-V compounds and a method for manufacturing such a light emitting diode.

2. The Prior Arts

Conventionally, the quaternary AlGaInP compound made of III-V elements is grown on the substrate made of GaAs to form the LED with high brightness. However, the bandgap for GaAs is small (about 1.424 ev) so that the light emitted by the LED containing quaternary AlGaInP compound is absorbed by the substrate made of GaAs, and thus the brightness of the LED is greatly reduced. U.S. Pat. No. 5,376,580 disclosed that after completion of epitaxial growth of the light emitting layer, the substrate which can absorb light was completely removed, and the the light emitting layer was joined to the transparent substrate made of GaP using wafer bonding techniques. Moreover, U.S. Pat. No. 5,008,718 disclosed that after completion of epitaxial growth of the light emitting layer, a thick transparent substrate made of GaP was epitaxially grown on the the light emitting layer, and then the substrate which can absorb light was completely removed, and subsequently the window layer was grown. However, the manufacturing process is not only complicated but also difficult, and thereby the manufacturing cost is increased.

In order to overcome such shortcomings, the present invention provides a light emitting diode made of III-V compounds and a method for manufacturing such a light emitting diode.

### SUMMARY OF THE INVENTION

Accordingly, the present invention provides a light emitting diode and a method for manufacturing such a light emitting diode in order to substantially obviate one or more of the problems due to limitations, shortcomings, and disadvantages of the related art.

The primary objective of the present invention is to provide a substrate with high light transmission by adjusting the proportions of the elements in the III-V compound of the substrate so as to minimize the brightness loss of the light emitting layer.

Another objective of the present invention is to provide a highly transparent window layer made of III-V compound and overlying the light emitting layer to minimize the brightness loss of the light emitting layer.

A further objective of the present invention is to provide a thick window layer made of III-V compound and overlying the light emitting layer to enhance the current distribution.

In order to achieve the above-mentioned objectives, the present invention provides a light emitting diode and a method for manufacturing such a light emitting diode. The light emitting diode comprises: a transparent substrate made of AlₓGa₁₋ₓAs; a light emitting layer made of AlGaInP, stacked on the transparent substrate, and having a multiple layered epitaxially growing structure; a window layer made of GaP, stacked on the light emitting layer, and having a transparent structure with a great bandgap; an upper electrode layer for making electrical contact with the window layer; and a lower electrode layer for making electrical contact with the transparent substrate, wherein the x-value in AlₓGa₁₋ₓAs of the transparent substrate is set to corresponding to the emission wavelengths of the light emitting layer so that the transparent substrate can have a great bandgap which make it to be transparent to the light emitted by the light emitting layer; and the window layer is used to increase the current diffusion from the upper electrode layer to the light emitting layer, and thereby the emission efficiency of the light laterally emitted by the light emitting layer is increased.

These and other objectives and functions of the present invention will be apparent to those skilled in the art by reading the following detailed description of a preferred embodiment thereof, with reference to the attached drawings.

### BRIEF DESCRIPTION OF THE DRAWINGS

FIGS. 1A to 1E illustrate schematically the steps performed during the manufacture of the light emitting diode of the present invention; and

FIG. 2 is a cross-sectional view of the light emitting diode according to one embodiment of the present invention.

### DETAILED DESCRIPTION OF THE PREFERRED EMBODIMENT

The following descriptions are exemplary embodiments only, and are not intended to limit the scope, applicability or configuration of the invention in any way.

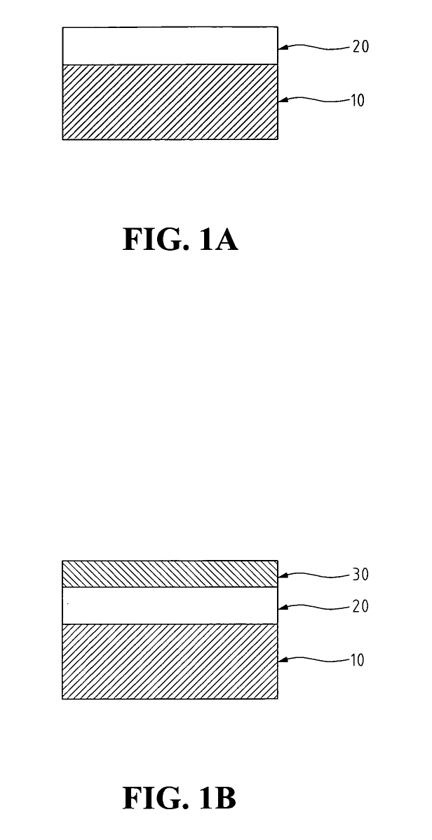

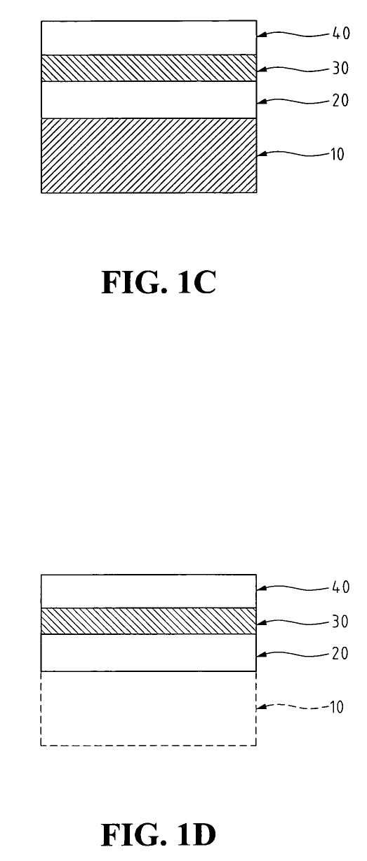

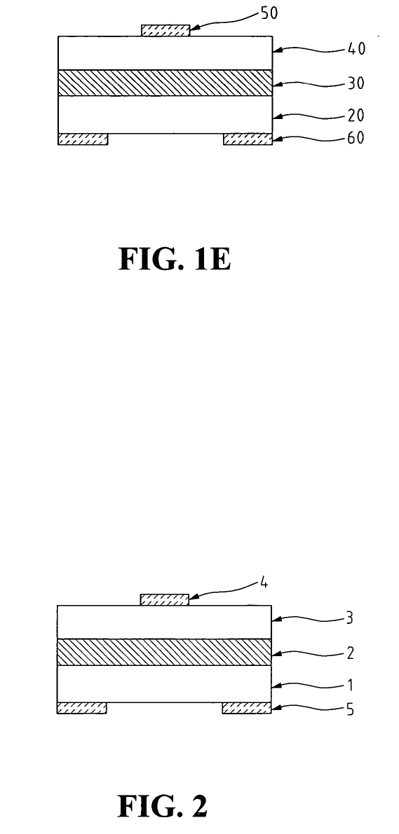

FIGS. 1A to 1E illustrate schematically the steps performed during the manufacture of the light emitting diode of the present invention.

Referring to FIGS. 1A to 1E, the present invention provides a highly transparent light emitting diode made of III-V compounds and a method for manufacturing such a light emitting diode. As shown in FIG. 1A, a first epitaxial layer 20 is grown on the substrate 10 using liquid phase epitaxy (LPE). The first epitaxial layer has a thickness in the range of 50 μm to 100 μm. Both of the first epitaxial layer 20 and the substrate 10 are made of the III-V compounds, wherein the substrate 10 is made of GaAs, and the first epitaxial layer 20 is made of AlGaAs. As shown in FIG. 1B, a second epitaxial layer 30 is grown on the first epitaxial layer 20 using metalorganic chemical vapor deposition (MOCVD). The second epitaxial layer 30 is made of AlGaInP, and has a multiple layered structure as a light emitting layer. The light emitting layer can be any conventional light emitting layer made of the quaternary AlGaInP compound. As shown in FIG. 1C, a third epitaxial layer 40 is grown on the second epitaxial layer 30 using MOCVD or hydride vapour phase epitaxy (HVPE). The third epitaxial layer 40 is made of GaP, and has a thickness in the range of 2 μm to 150 μm. As shown in FIG. 1D, the substrate 10 made of GaAs is then removed by etching. A metal layer is formed on the top surface of the third epitaxial layer 40, and another metal layer is formed on the bottom surface of the first epitaxial layer 20. Both of the metal layers are patterned to respectively form the first electrode layer 50 and the second electrode layer 60, which act as the excitation electrodes of the light emitting diode of the present invention. Each of the two electrode layers makes electrical contact with its corresponding epitaxial layer.

In the above step, the substrate 10 is made of GaAs which has a small bandgap of 1.424 eV so that the light emitted by the second epitaxial layer 30 can be absorbed by the substrate 10, and thus the light emitting efficiency is greatly reduced. Therefore, the the substrate 10 made of GaAs is removed in the present invention.

The first epitaxial layer 20 is made of AlGaAs which has the formula AlGa₁₋ₓAs, wherein the larger the x-value is, the greater the bandgap of AlGaAs is. Because the degree of transparency is varied with the emission wavelength, the the x-value in AlₓGa₁₋ₓAs of the first epitaxial layer 20 is determined by the emission wavelength of the second epitaxial layer 30 so that the first epitaxial layer 20 is highly transparent to the light emitted by the second epitaxial layer 30. For example, for the second epitaxial layer 30 made of AlGaInP, x is in the range of from 0.45 to 0.9. The first epitaxial layer 20 is highly transparent to any light emitted by the second epitaxial layer 30 of AlGaInP if x is set to about 0.8.

FIG. 2 is a cross-sectional view of the light emitting diode according to the embodiment of the present invention.

Referring to FIG. 2, The light emitting diode of the present invention comprises: a transparent substrate 1, a light emitting layer 2, and a window layer 3 sequentially formed in this order from bottom to top; a metal upper electrode 4 for making electrical contact with the top surface of of the window layer 4; and a lower electrode layer 5 for making electrical contact with the bottom surface of the transparent substrate 1.

In the light emitting diode of the present invention, the transparent substrate 1 is an epitaxial layer made of AlₓGa₁₋ₓAs, wherein the x-value is corresponding to the emission wavelength of the light emitting layer 2. The suitable x-value is set so that the transparent substrate 1 can highly transmit light. The light emitting layer 2 has a light emitting structure of conventional quaternary AlGaInP compound made of III-V elements. The light emitting layer 2 comprises at least an active layer, an upper confining layer, and a lower confining layer. The window layer 3 is made of GaP, and has a transparent structure with a great bandgap. The window layer 3 is used to increase the current diffusion from the upper electrode layer 4 to the light emitting layer 2, and thereby the emission efficiency of the light laterally emitted by the light emitting layer 2 is increased.

In addition, the upper and lower electrodes can be made of transparent and conductive oxides, which can enhance the brightness of the light emitting diode of the present invention.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. A light emitting diode, comprising:
a transparent substrate made of AlₓGa₁₋ₓAs;
a light emitting layer made of AlGaInP, and stacked on the transparent substrate;
a window layer stacked on the light emitting layer;
an upper electrode layer, which makes electrical contact with the window layer; and
a lower electrode layer, which makes electrical contact with the transparent substrate,
wherein the x-value in the transparent substrate of AlₓGa₁₋ₓAs is set to corresponding to an emission wavelength of the light emitting layer so that the transparent substrate can have a great bandgap which make it to be transparent to a light emitted by the light emitting layer, and the window layer is used to increase a current diffusion from the upper electrode layer to the light emitting layer.

2. The light emitting diode as claimed in claim 1, wherein the transparent substrate has a thickness in the range of 50 μm to 100 μm.

3. The light emitting diode as claimed in claim 1, wherein the window layer has a transparent structure with a great bandgap, and is made of III-V compound.

4. The light emitting diode as claimed in claim 3, wherein the window layer is made of GaP.

5. The light emitting diode as claimed in claim 4, wherein the window layer has a thickness in the range of 2 μm to 150 μm.

6. A method for manufacturing a light emitting diode comprising the steps of:
growing a first epitaxial layer made of AlₓGa₁₋ₓAs on a substrate using an epitaxy method;
growing a second epitaxial layer made of AlGaInP on the first epitaxial layer using metalorganic chemical vapor deposition to act as a light emitting layer;
growing a third epitaxial layer made of III-V compound on the second epitaxial layer;
removing the substrate by etching;
forming a patterned electrode layer on a top surface of the third epitaxial layer to act as an excitation electrode; and
forming a patterned electrode layer on a bottom surface of the first epitaxial layer to act as an excitation electrode,
wherein each of the electrode layer makes electrical contact with its corresponding epitaxial layer, and the x-value in AlₓGa₁₋ₓAs of the first epitaxial layer is set to corresponding to emission wavelengths of the light emitting layer so that the substrate can have a great bandgap which make it to be transparent to light emitted by the light emitting layer.

7. The method as claimed in claim 6, wherein in the step of growing the first epitaxial layer on the substrate using the epitaxy method, the epitaxy method is a liquid phase epitaxy method.

8. The method as claimed in claim 6, wherein in the step of growing the first epitaxial layer on the substrate using the epitaxy method, the substrate is made of GaAs.

9. The method as claimed in claim 6, wherein in the step of growing the first epitaxial layer on the substrate using the epitaxy method, the first epitaxial layer has a thickness in the range of 50 μm to 100 μm.

10. The method as claimed in claim 6, wherein in the step of growing the first epitaxial layer on the substrate using the epitaxy method, x-value is in the range of from 0.45 to 0.9.

11. The method as claimed in claim 10, wherein in the step of growing the first epitaxial layer on the substrate using the epitaxy method, x-value is 0.8.

12. The method as claimed in claim 6, wherein in the step of growing the third epitaxial layer on the second epitaxial layer, the third epitaxial layer is made of GaP.

13. The method as claimed in claim 12, wherein in the step of growing the third epitaxial layer on the second epitaxial layer, the third epitaxial layer has a thickness in the range of 2 μm to 150 μm.

14. The method as claimed in claim 6, wherein in the step of growing the third epitaxial layer on the second epitaxial layer, the metalorganic chemical vapor deposition method is used for growing the third epitaxial layer on the second epitaxial layer.

15. The method as claimed in claim 6, wherein in the step of growing the third epitaxial layer on the second epitaxial layer, the hydride vapor phase epitaxy method is used for growing the third epitaxial layer on the second epitaxial layer.
